(19) United States
(12) Patent Application Publication
(10) Pub. No.: US 2018/0241394 A1
(43) Pub. Date: Aug. 23, 2018

(54) METHOD OF OPERATING A CAPACITIVE SENSOR SYSTEM FOR VEHICLE TRUNK OPENER AND ROBUST CAPACITIVE SENSOR SYSTEM

(71) Applicant: IEE INTERNATIONAL ELECTRONICS & ENGINEERING S.A., Echternach (LU)

(72) Inventors: Michael VIRNICH, Korlingen (DE); Laurent LAMESCH, Reichlange (LU)

(21) Appl. No.: 15/752,179

(22) PCT Filed: Aug. 12, 2016
(86) PCT No.: PCT/EP2016/069292

§ 371 Date: Feb. 12, 2018

(30) Foreign Application Priority Data
Aug. 13, 2015 (LU) 92 798
Dec. 21, 2015 (LU) 92 919

(51) Int. Cl. H03K 17/955; G07C 9/00; E05F 15/70

(52) U.S. Cl. CPC H03K 17/955; G07C 9/00309; E05Y 2900/546; H03K 2217/960735; E05F 15/70

(57) ABSTRACT

A method of operating a capacitive loading-mode sensor system with regard to generating a trigger signal indicative of an occurrence of an event. The capacitive loading-mode sensor system includes at least one capacitive sensor and a sensor control unit configured for operating the at least one capacitive sensor in loading mode and including a signal generating unit and a signal evaluation unit. Based on acquired real part and imaginary part of the momentary sensor output signal, an absolute value of change of at least one out of a complex impedance or a complex admittance sensed by the at least one capacitive sensor is determined, and a trigger signal is generated by the signal evaluation unit if at least one predetermined condition concerning the determined absolute value of change of the complex impedance or the complex admittance is fulfilled.

### TECHNICAL FIELD

The present invention relates to method of operating a capacitive loading-mode sensor system with regard to generating a trigger signal indicative of an occurrence of an event, a control system for controlling activation of a motor-driven vehicle door member using such method, and a software module for carrying out the method.

### BACKGROUND OF THE INVENTION

Automatic actuation of motorized tailgates of motor vehicles controlled by using capacitive sensors is known in the art.

For instance, utility model document DE 20 2005 020 140 U1 describes a motor vehicle door arrangement with at least one motor vehicle door and a drive for motorized movement of the motor vehicle door from the closed position into the open position and from the open position into the closed position. The arrangement further comprises a control for triggering the drive, the control being assigned an optionally actuatable mobile part which the user generally carries and which interacts with the control means over a wireless transmission link when the user approaches the motor vehicle, enhanced activation automatically carrying out opening and/or a closing as triggered by a predetermined process of use and without the necessity of activating the mobile part. In one embodiment, provision is made for a user-side operator control event, namely a user-side foot movement, to cause the motorized opening of the tailgate. With respect to enhanced activation, the control means, especially with the vehicle stopped, can be moved into the activated and deactivated states, and can be triggered by the predetermined usage process exclusively when the control means is in the activated state.

Further, international application WO 2012/084111 A1 describes a closure element assembly of a motor vehicle having a motor-displaceable closure element, wherein a sensor assembly and a sensor controller are provided for generating an operating message. By means of the operating message, motor displacement of the closure element can be triggered. The sensor controller monitors the sensor-measured values during operating event monitoring. During fault situation monitoring, the sensor controller monitors the sensor-measured values for the occurrence of a behavior that is characteristic of a fault situation.

During the fault situation monitoring process, the sensor controller increments a “fault indicator” variable if an indication of a fault is registered at the monitoring time and, when a predetermined threshold value for the fault indicator is exceeded, a fault situation is registered as true in the sensor controller. The sensor controller generates an operating message only when, according to the two monitoring actions, an operating event but no fault situation is present.

### SUMMARY AND OBJECTS OF THE INVENTION

Ideally, capacitive loading-mode sensor systems for kick-triggered vehicle trunk openers should fulfil the following requirements:
(i) robustness regarding electromagnetic interference (EMI) to meet electromagnetic compatibility (EMC) requirements
(ii) capability to operate satisfactorily at all potential ambient conditions, including rainfall and wet street condition from rain and/or salt water, or with a vehicle having electrically conductive bumpers,
(iii) full functionality within a given set of external parameters including length of cable harness from capacitive loading-mode sensor system to vehicle chassis ground and sensor offset capacitance.

At measurement frequencies of about 100 kHz (i.e. significantly below 500 kHz) as used in today's capacitive loading-mode sensor systems that are employed, for instance, for vehicle trunk opener systems, an effect of the inductance of the electrical connection from the capacitive sensor system and the vehicle chassis ground can be neglected, whereas the effect of the inductance becomes more and more pronounced when approaching frequencies of about 500 kHz and above. At these frequencies, the inductance of the electrical connection from the capacitive sensor system to vehicle chassis ground and the sensor offset capacitance to the vehicle chassis form a series resonance circuit, whose impedance drops significantly if the measurement frequency has been chosen close to or equal to a resonance frequency of the series resonance circuit. Thus, if the measurement frequency is constant and significantly larger than 500 kHz, the change in sensed imaginary part, which is equal to the capacitance can drop substantially depending on the physical values of the offset capacitance and the electrical connection (given, for instance, by an inductance of a cable harness) between the capacitive sensor system and the vehicle chassis ground.

An equivalent circuit diagram of the above-described scenario is illustrated in FIG. 2. Therein, the following denotation and lay-out applies:

| | | | |
|---|---|---|---|
| C1 | capacitance between capacitive sensor and vehicle | 50 | pF |
| | chassis (sensor offset capacitance to vehicle chassis) | | |
| C2 | capacitance between capacitive sensor and ground | 5 | pF |
| C3 | EMC capacitor for EMI protection | 120 | pF |
| C5 | capacitance between vehicle chassis and ground | 200 | pF |
| Ck | change in capacitance between capacitive sensor | 1 | pF |
| | and ground | | |
| R1 | resistor | 100 | Ω |
| R3 | resistor | 100 | Ω |
| Ls | inductance of capacitive sensor | 100 | nH |
| Lh | inductance of cable harness from capacitive sensor | 2 | μH |
| | to chassis | | |

A simulation result for this scenario is given in FIG. 4, which shows the determined difference in capacitance (solid line, left axis) and the relative phase (dashed line, right axis) for a simulated change in capacitance Ck of 1 pF as a function of the frequency of a time-varying output signal that is applied to the capacitance sensor. In the frequency range between 1 MHz and about 5 MHz, a sensitivity of the capacitive loading-mode sensor system drops to zero sensitivity. Above 5 MHz, the relative phase difference is changed to 180° so that the simulated change in capacitance Ck has an inverse effect on the capacitance sensor.

On the other hand, a measurement frequency of about 500 kHz or more enables robust operational functionality even at salt water condition or with vehicles having electrically conductive bumpers. On the downside, the higher measurement frequency is inherently more susceptible to electromagnetic interference due to the larger signal bandwidth.

It is therefore desirable to have a capacitive loading-mode sensor system available with improved properties concerning the above conditions (i) to (iii).

In one aspect of the present invention, there is provided a method of operating a capacitive loading-mode sensor system with regard to generating a trigger signal indicative of an occurrence of an event. The capacitive loading-mode sensor system comprises at least one capacitive sensor configured to generate a sensor output signal indicative of an occurrence of an object approaching the capacitive sensor. The capacitive loading-mode sensor system further includes a sensor control unit configured for operating the at least one capacitive sensor in loading mode. The sensor control unit includes a signal generating unit that is configured for generating a time-varying output signal and for providing the time-varying output signal to the at least one capacitive sensor, and a signal evaluation unit that is provided for sensing a real part and an imaginary part of the sensor output signal.

The method of operating concerns generating a trigger signal indicative of the sensor output signal fulfilling at least one predetermined condition. The method comprises steps of
by the signal generating unit, providing the time-varying output signal to the at least one capacitive sensor for operating the at least one capacitive sensor in loading mode,
acquiring a momentary sensor output signal at a specified sampling time,
based on the acquired real part and imaginary part of the momentary sensor output signal, determining an absolute value of change of at least one out of a complex impedance or a complex admittance sensed by the at least one capacitive sensor,
checking if the determined absolute value fulfills the at least one predetermined condition, and
generating a trigger signal by the signal evaluation unit if the at least one predetermined condition is fulfilled.

The term “vehicle”, as used in this application, shall particularly be understood to encompass passenger cars, trucks and buses.

The term “loading mode”, as used in this application, shall be understood particularly as a mode of measuring a displacement current caused by the presence of a grounded object in proximity of a single sense electrode (cf. J. Smith et al., Electric field sensing for graphical interfaces, IEEE Comput. Graph. Appl., 18(3):54-60, 1998).

By evaluating the acquired real part and imaginary part of the momentary sensor output signal and determining an absolute value of change of at least one out of a complex impedance or a complex admittance sensed by the at least one capacitive sensor, the above-discussed functional degrading or even loss of functionality can be avoided.

FIG. 5 illustrates a simulation result for a change in capacitance as obtained from determining an absolute value of change in complex admittance Y sensed by the capacitive sensor, for a simulated change in capacitance of 1 pF as a function of the frequency of a time-varying output signal that is applied to the capacitance sensor. In contrast to the results shown in FIG. 4, only a small loss of sensitivity is observable for frequencies of the time-varying output signal up to 10 MHz.

The simulation is based on an equivalent circuit diagram illustrated in FIG. 3. Therein, the following denotation holds:

| | | | |
|---|---|---|---|
| C8 | capacitance between capacitive sensor and vehicle | 50 | pF |
| | chassis (sensor offset capacitance to vehicle chassis) | | |
| C9 | EMC capacitor for EMI protection | 120 | pF |
| C10 | capacitance between capacitive sensor and ground | 5 | pF |
| C13 | capacitance between vehicle chassis and ground | 200 | pF |
| Ck | change in capacitance between capacitive sensor | 1 | pF |
| | and ground | | |
| R2 | | 100 | Ω |
| R4 | | 100 | Ω |
| Ls | inductance of capacitive sensor | 100 | nH |
| Lh | inductance of cable harness from capacitive sensor | 2 | μH |
| | to chassis | | |

Alternatively, the change in capacitance can also be obtained from determining an absolute value of change in complex impedance Z sensed by the capacitive sensor, as the real and imaginary parts of the admittance Y can be expressed in terms of the real and imaginary parts of the impedance Z, and vice versa:

with Y=G+j·B and Z=R+j·X,

wherein G denotes the conductance, B the susceptance, R the resistance and X the reactance, it follows that

$$G = \frac{R}{{R}^{2} + {X}^{2}} , B = \frac{- X}{{R}^{2} + {X}^{2}} R = \frac{G}{{G}^{2} + {B}^{2}} and X = \frac{- B}{{G}^{2} + {B}^{2}}$$

If the step of acquiring the momentary sensor output signal comprises digitally converting the acquired momentary sensor output signal, the benefits of well-known methods of digital signal processing can be applied to the subsequent steps of the method.

In a preferred embodiment of the method, the step of providing the time-varying output signal comprises providing a time-varying output signal with a fundamental frequency of at least 1.0 MHz. The term “fundamental frequency”, as used in this application, shall be understood particularly as a lowest sinusoidal frequency in a Fourier analysis of the time-varying output signal. More preferable, the fundamental frequency is at least 3 MHz.

In this way, a capability to operate the capacitive loading-mode sensor system satisfactorily at a large number of all potential ambient conditions, including rainfall and wet street condition from rain and/or salt water, or with a vehicle having electrically conductive bumpers, can be accomplished.

Preferably, the time-varying output signal has one out of a sinusoidal shape or a square wave shape. The sinusoidal shape provides the advantage of a single definite operation frequency. The square wave shape has substantial amplitudes at odd harmonic frequencies (3f, 5f, 7f, . . . ) so that a substantial portion of the amplitude of the time-very output signal lies in a frequency range that is beneficial for operating the capacitive loading-mode sensor system satisfactorily at a large number of potential ambient conditions.

In some embodiments of the method, the at least one predetermined condition is given by a temporal course of the absolute value of change of at least one out of the complex impedance or the complex admittance sensed by the at least one capacitive sensor to cross a predetermined threshold value for the absolute value of change of the complex impedance or the complex admittance.

In this way, an object approaching the at least one capacitive sensor can reliably be detected at a large number of potential ambient conditions and vehicle designs.

In some embodiments of the method, the at least one predetermined condition can comprise a temporal pattern in the determined absolute values of change of at least one out of a complex impedance or a complex admittance sensed by the at least one capacitive sensor. In one embodiment, the temporal pattern can comprise crossing a predetermined threshold value in different directions within a specified time period.

In some embodiments of the method, the event is formed by an operator-intended event and the trigger signal is designed as an input to a control system for controlling an activation of a motor-driven vehicle door member. In this way, the method can, for instance, beneficially be employed for operating capacitive loading-mode sensor systems for kick-triggered vehicle trunk openers, and can fulfill the above-mentioned requirements (i) to (iii) to a large extent.

A robust and reliable operation of the capacitive loading-mode sensor system with regard to generating a trigger signal indicative of an occurrence of an event can be accomplished if the method further includes steps of
determining an extreme absolute value of change of at least one out of the complex impedance or the complex admittance sensed by the at least one capacitive sensor during carrying out one of the operator-intended events, wherein the determining is carried out subsequently for a plurality of operator-intended events, and
determining the predetermined threshold value based on the results of determining the extreme absolute values of change of at least one out of the complex impedance or the complex admittance.

The term “extreme absolute value”, as used in this application, shall be understood particularly as a minimum or a maximum of the absolute value.

In some embodiments, the step of determining the predetermined threshold value based on the results of determining the extreme absolute values comprises a step of averaging of at least a sub-set of the determined extreme absolute values.

In some embodiments of the method, wherein the capacitive loading-mode sensor system forms part of a control system for controlling activation of a motor-driven vehicle door member of a vehicle, and wherein the at least one capacitive sensor is arranged close to specific parts of the vehicle such that the specific parts interact with an electromagnetic field that is generated by the at least one capacitive sensor upon providing the time-varying output signal, the method further comprises a step of tuning at least one out of the fundamental frequency of the time-varying output signal of the signal generating unit and a resonance frequency of a resonance circuit formed by the specific parts of the vehicle such that the fundamental frequency or one of higher harmonics of the time-varying output signal of the signal generating unit lies in a regime in close proximity to the resonance frequency.

The term “a regime in close proximity to the resonance frequency”, as used in this application, shall be understood particularly as a frequency regime about the resonance frequency that preferably has a range that corresponds to a full width at half maximum (FWHM), and, more preferable, has a range that corresponds to 1.5 times the FWHM.

In this way, by using the resonance characteristic of the resonance circuit formed by the specific parts of the vehicle, a sensitivity increase of the capacitive loading-mode sensor system can be achieved.

Preferably, the step of tuning includes electrically connecting at least one out of a capacitor or an inductor in series to the at least one capacitive sensor. In this way, the step of tuning can readily be accomplished with little hardware effort. The capacitor or inductor may e.g. comprise a component which is switchably connectable in series with the capacitive sensor. In other embodiments, the capacitor or inductor may comprise a component, e.g. an SMD component, which is permanently mounted in the corresponding circuit.

In another aspect of the invention, a control system for controlling activation of a motor-driven vehicle door member is provided. The control system comprises
at least one processor unit and at least one digital data memory unit, wherein the at least one processor unit has data access to the at least one digital data memory unit,
at least one capacitive sensor configured to generate a sensor output signal indicative of an occurrence of an (grounded) object approaching the capacitive sensor,
a sensor control unit configured for operating the at least one capacitive sensor in loading mode, the sensor control unit including a signal generating unit that is configured for generating a time-varying output signal and for providing the time-varying output signal to the at least one capacitive sensor, and a signal evaluation unit that is provided for sensing a real part and an imaginary part of the sensor output signal.

The at least one processor unit is configured for carrying out steps of any embodiment of the method disclosed herein.

The at least one processor unit is configured to receive the trigger signal from the signal evaluation unit and, upon and as long as receiving the trigger signal from the signal evaluation unit, to generate an output signal for at least initiating an activation of the motor-driven vehicle door member.

In this way, a control system for controlling activation of a motor-driven vehicle door member can be provided that can be robust with regard to electromagnetic interference, that can provide full functionality at a large number of potential ambient conditions and vehicle designs, for instance in the presence of an electrically conductive bumper of the vehicle and within a given set of external parameters including length of cable harness to vehicle chassis ground and sensor offset capacitance.

In a further aspect of the invention, a software module is provided for carrying out an embodiment of the method disclosed herein, wherein the method steps to be conducted are converted into a program code of the software module that is implementable in a digital data memory unit and that is executable by a processor unit. The processor unit may preferably be the processor unit of a control system for controlling activation of a motor-driven vehicle door member.

The software module can enable a robust and reliable execution of the method and can allow for a fast modification of method steps.

These and other aspects of the invention will be apparent from and elucidated with reference to the embodiments described hereinafter.

### BRIEF DESCRIPTION OF THE DRAWINGS

Preferred embodiments of the invention will now be described, by way of example, with reference to the accompanying drawings, in which:

FIG. 1 is a schematic illustration of a control system in accordance with the invention;

FIG. 2 schematically illustrates an equivalent circuit diagram of the capacitive loading-mode sensor portion of the control system pursuant to FIG. 1 in relation to specific vehicle parts;

FIG. 3 schematically illustrates the equivalent circuit diagram pursuant to FIG. 2 for the presence of an operator-intended event;

FIG. 4 shows a simulation result for the occurrence of an operator-intended event, based on the equivalent circuit diagrams pursuant to FIGS. 2 and 3 and applying a conventional method of operating a capacitive sensor system;

FIG. 5 shows a simulation result based on the equivalent circuit diagrams pursuant to FIGS. 2 and 3 and applying a method in accordance with the invention; and

FIG. 6 shows a simulation result based on the equivalent circuit diagrams pursuant to FIGS. 2 and 3 and applying a method in accordance with the invention that includes a step of tuning.

### DESCRIPTION OF PREFERRED EMBODIMENTS

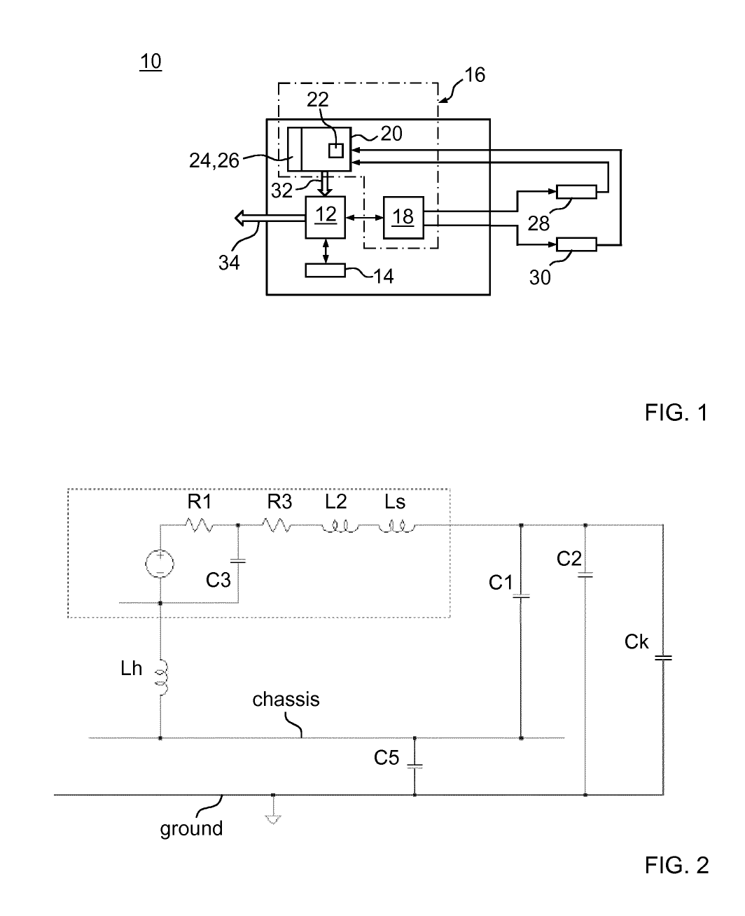

FIG. 1 schematically illustrates a control system 10 for controlling activation of a motor-driven vehicle door member in accordance with an embodiment of the invention. The vehicle door member is formed by a tailgate. The control system 10 includes a processor unit 12 and a digital data memory unit 14 to which the processor unit 12 has data access. The control system 10 further comprises two capacitive sensors 28, 30 which are configured to generate sensor output signals that are indicative of the occurrence of objects approaching the capacitive sensors 28, 30. To this end, the control system 10 includes a sensor control unit 16 that is configured for operating the two capacitive sensors 28, 30 in loading mode.

The sensor control unit 16 comprises a signal generating unit 18 that is electrically connected to the two capacitive sensors 28, 30 and is configured for generating a time-varying output signal and for providing the time-varying output signal to the two capacitive sensors 28, 30. The time-varying output signal is designed as a square wave having a fundamental frequency of 3 MHz. Each one of the two capacitive sensors 28, 30 is configured to generate a sensor output signal having a real part and an imaginary part, and being indicative of a sensed distance to an object, in particular a foot of an operator, as will be described in the following.

The control system 10 further comprises a signal evaluation unit 20 that is connected to output ports of the capacitive sensors 28, 30 and is configured for receiving the sensor signals as signal inputs. The connection between the signal evaluation unit 20 and the capacitive sensors 28, 30 may be wire-based or wireless. The signal evaluation unit 20 is configured for sensing the real part and the imaginary part of the sensor output signal. To this end, and for carrying out other functions that will be described further below, the sensor signal evaluation unit 20 is equipped with a processor unit 22 and a digital data memory 24 of its own.

A configuration of the control system 10 and the capacitive sensors 28, 30 that are arranged at locations close to the vehicle tailgate is similar to those known in the art, for instance from international application WO 2012/084111 A1 mentioned in the introductory part of this application, and shall therefore not be described in more detail herein.

The signal evaluation unit 20 is equipped with a software module 26 for carrying out a method of operating a capacitive loading-mode sensor system with regard to generating a trigger signal 32 indicative of an occurrence of an event. The event is formed by an operator-intended event forming a kicking motion of an operator's foot close to the vehicle tailgate.

The trigger signal 32 is intended and designed as an input from the signal evaluation unit 20 to the processor unit 12 of the control system 10. The method steps to be conducted are converted into a program code of the software module 26, wherein the program code is implemented in the digital data memory 24 of the signal evaluation unit 20 and is executed by the processor unit 22 of the signal evaluation unit 20. As an alternative, a portion of the method steps, being converted into a program code of the software module 26, can be implemented in the digital data memory unit 14 of the control system 10 and can be executed by the processor unit 12 of the control system 10.

In the following, an embodiment of the method will be described. In preparation of operating the capacitive loading-mode sensor system, it shall be understood that all involved units, devices and systems are in operational state and configured as illustrated in FIG. 1. Magnitudes of the signals of the capacitive sensors 28, 30 are being monitored by the sensor signal evaluation unit 20. Execution of the method steps is started if the magnitude of at least one of the output signals of the capacitive sensors 28, 30 exceeds an activation threshold. After that, the method steps are automatically repeated until the magnitudes of the output signals of the capacitive sensors 28, 30 fall below the activation threshold.

Although only described for one of the capacitive sensors 28, 30 in the following, the disclosed method steps are understood to be applied to each one of the two capacitive sensors 28, 30.

In a first step of the method the time-varying output signal is provided to the capacitive sensor 28, 30 by the signal generating unit 18, for operating the capacitive sensor 28, 30 in loading mode.

In a next step of the method, a momentary sensor output signal is acquired by the signal evaluation unit 20 at specified sampling times, i.e. with a constant sampling rate, and the acquired momentary sensor output signal is digitally converted for further signal processing. The sampling rate is selected such that the time between two successive samples is half of the period time of the highest frequency expected for the sensor output signal to prevent aliasing.

In a next step, the signal evaluation unit 20 determines an absolute value of change of a complex admittance sensed by the capacitive sensor 28, 30, on the basis of a real part and imaginary part of the acquired momentary sensor output signal.

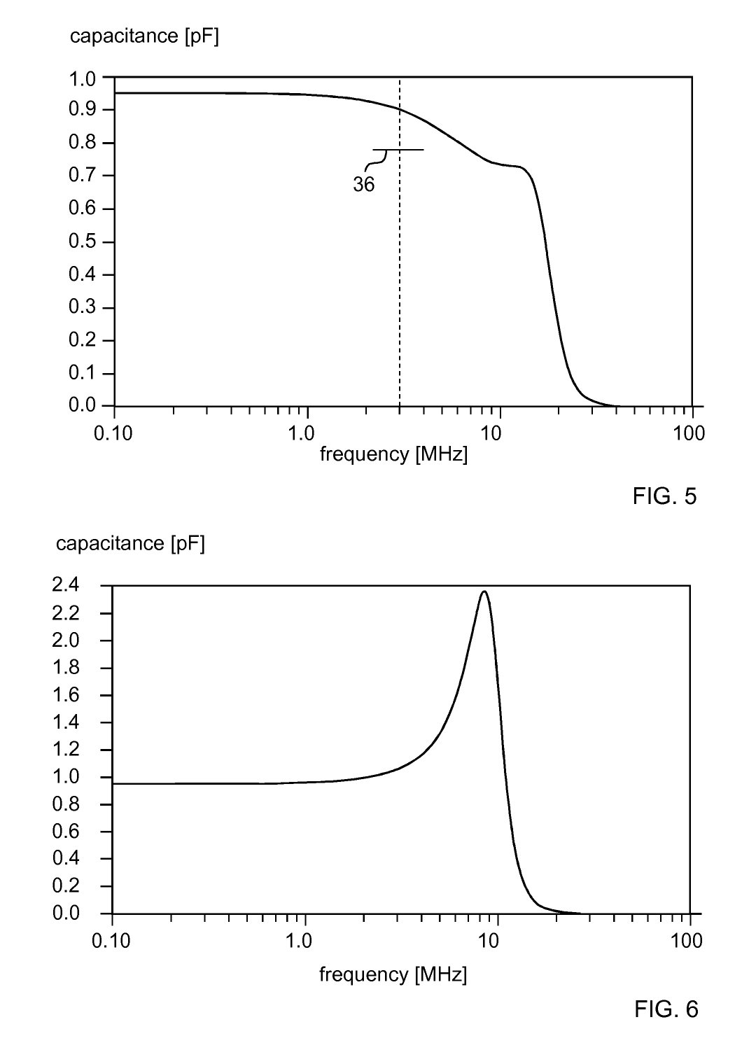

In another step then, the signal evaluation unit 20 checks if the determined momentary absolute value of change of the complex admittance fulfills the at least one predetermined condition, which is given by a temporal course of the absolute value of change of the complex admittance sensed by the capacitive sensor 28, 30 to cross a predetermined threshold value 36 (FIG. 5) for the absolute value of change of the complex admittance.

The predetermined threshold value 36 has been obtained in a calibration procedure, in which, for each one of a plurality of subsequently carried out operator-intended events, an extreme absolute value of change of the complex admittance sensed by the capacitive sensor 28, 30 during carrying out one of the operator-intended events has been determined. The determined extreme absolute values of change of the complex admittance have been averaged in order to derive the predetermined threshold value 36.

If the predetermined condition is fulfilled, the signal evaluation unit 20 generates a trigger signal 32 that is designed as an input to the processor unit 12 of the control system 10 for controlling an activation of the motor-driven vehicle door member in a next step.

The processor unit 12 of the control system 10 will generate an output signal 34 for initiating an activation of the motor-driven vehicle door member, upon receiving the trigger signal 32 from the signal evaluation unit 20. As the steps are carried out in a repetitive manner, the output signal 34 will be maintained as long as the trigger signal 32 from the signal evaluation unit 20 is provided to the processor unit 12 of the control system 10.

If the predetermined condition is not fulfilled, the generation of the trigger signal 32 is omitted, and no control unit output signal 34 is generated.

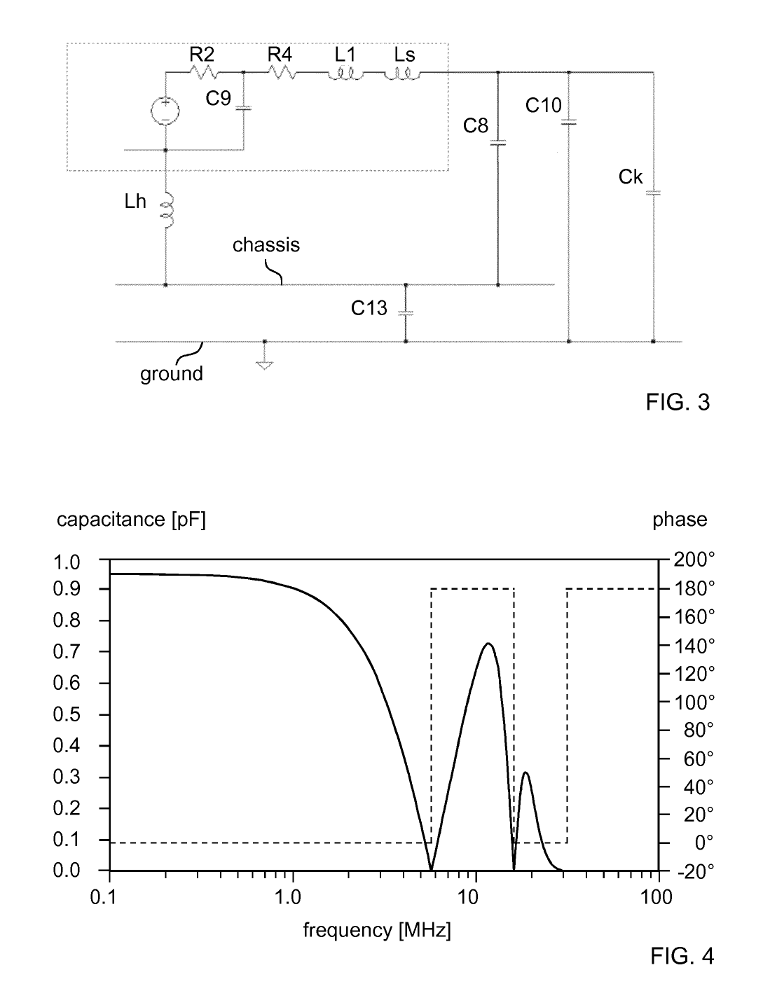

As mentioned before, the capacitive sensors 28, 30 are arranged close to the vehicle tailgate, such that specific parts of the vehicle interact with electromagnetic field that is generated by the capacitive sensors 28, 30 upon providing the time-varying output signal by the signal generating unit 18. This interaction is reflected in the equivalent circuit diagrams as shown in FIGS. 2 and 3.

In an alternative embodiment of the method, a step of tuning a resonance frequency of a resonance circuit formed by the specific parts of the vehicle such that the fundamental frequency or one of higher harmonics of the time-varying output signal of the signal generating unit 18 lies in a regime in close proximity to the resonance frequency. The step of tuning is carried out by electrically connecting an inductor L1, L2 in series to each one of the capacitive sensors 28, 30 (FIG. 2 and FIG. 3). The inductor L1, L2 has an inductance of about 4 μH. A simulation result that is based on one of the equivalent circuit diagrams as shown in FIGS. 2 and 3 is illustrated in FIG. 6, showing the benefit in terms of sensitivity of the capacity loading mode sensor system due to the proximity of the frequency of the time-varying output signal to the resonance frequency.

It will be appreciated that the capacitor or inductor may e.g. comprise a component which is switchably connectable in series with the capacitive sensor. In other embodiments, the capacitor or inductor may comprise a component, e.g. an SMD component, which is permanently mounted in the corresponding sensing circuit.

While an embodiment of the invention has been illustrated and described in detail in the drawings and foregoing description, such illustration and description are to be considered illustrative or exemplary and not restrictive; the invention is not limited to the disclosed embodiments.

Other variations to be disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. The mere fact that certain measures are recited in mutually different dependent claims does not indicate that a combination of these measures cannot be used to advantage. Any reference signs in the claims should not be construed as limiting scope.

1. A method of operating a capacitive loading-mode sensor system with regard to generating a trigger signal indicative of an occurrence of an event, the capacitive loading-mode sensor system comprising
at least one capacitive sensor configured to generate a sensor output signal indicative of an occurrence of an object approaching the at least one capacitive sensor,
a sensor control unit configured for operating the at least one capacitive sensor, in loading mode, the sensor control unit including a signal generating unit that is configured for generating a time-varying output signal and for providing the time-varying output signal to the at least one capacitive sensor, and a signal evaluation unit that is provided for sensing a real part and an imaginary part of the sensor output signal,
wherein the method of operating concerns generating the trigger signal indicative of the sensor output signal fulfilling at least one predetermined condition, and the method comprising steps to be carried out in a repetitive manner of
by the signal generating unit, providing the time-varying output signal to the at least one capacitive sensor for operating the at least one capacitive sensor in loading mode,
acquiring a momentary sensor output signal at a specified sampling time,
based on the acquired real part and imaginary part of the momentary sensor output signal, determining an absolute value of change of at least one out of a complex impedance or a complex admittance sensed by the at least one capacitive sensor,
checking if the determined absolute value fulfills the at least one predetermined condition, and
generating a trigger signal by the signal evaluation unit if the at least one predetermined condition is fulfilled.

2. The method as claimed in claim 1, wherein the step of acquiring the momentary sensor output signal comprises digitally converting the acquired momentary sensor output signal.

3. The method as claimed in claim 1, wherein the step of providing the time-varying output signal comprises providing a time-varying output signal with a fundamental frequency of at least 1.0 MHz.

4. The method as claimed in claim 1, wherein the time-varying output signal has one out of a sinusoidal shape or a square wave shape.

5. The method as claimed in claim 1, wherein the at least one predetermined condition is given by a temporal course of the momentary absolute value of change of at least one out of the complex impedance or the complex admittance sensed by the at least one capacitive sensor to cross a predetermined threshold value for the absolute value of change of the complex impedance or the complex admittance.

6. The method as claimed in claim 1, wherein
the event is formed by an operator-intended event, and
the trigger signal is designed as an input to a control system for controlling an activation of a motor-driven vehicle door member.

7. The method as claimed in claim 6, further including steps of
subsequently for a plurality of operator-intended events, determining an extreme absolute value of change of at least one out of the complex impedance or the complex admittance sensed by the at least one capacitive sensor during carrying out one of the operator-intended events, and
determining the predetermined threshold value based on the results of determining the extreme absolute values of change of at least one out of the complex impedance or the complex admittance.

8. The method as claimed in claim 6, wherein the capacitive loading-mode sensor system forms part of a control system for controlling activation of a motor-driven vehicle door member of a vehicle, and wherein the at least one capacitive sensor, is arranged close to specific parts of the vehicle such that the specific parts interact with an electromagnetic field that is generated by the at least one capacitive sensor upon providing the time-varying output signal, and the method further comprising a step of
tuning at least one out of the fundamental frequency of the time-varying output signal of the signal generating unit and a resonance frequency of a resonance circuit formed by the specific parts of the vehicle such that the fundamental frequency or one of higher harmonics of the time-varying output signal of the signal generating unit lies in a regime in close proximity to the resonance frequency.

9. The method as claimed in claim 8, wherein the step of tuning includes electrically connecting at least one out of a capacitor or an inductor (L1, L2) in series to the at least one capacitive sensor.

10. A control system for controlling activation of a motor-driven vehicle door member, the control system comprising
at least one processor unit and at least one digital data memory unit, wherein the at least one processor unit has data access to the at least one digital data memory unit,
at least one capacitive sensor configured to generate a sensor output signal indicative of an occurrence of an object approaching the at least one capacitive sensor,
a sensor control unit configured for operating the at least one capacitive sensor in loading mode, the sensor control unit including
a signal generating unit that is configured for generating a time-varying output signal and for providing the time-varying output signal to the at least one capacitive sensor,
a signal evaluation unit that is provided for sensing a real part and an imaginary part of the sensor output signal,
and wherein the at least one processor unit is configured for carrying out steps of the method claim 1,
and wherein the at least one processor unit is configured to receive the trigger signal from the signal evaluation unit and, upon and as long as receiving the trigger signal from the signal evaluation unit, to generate an output signal for at least initiating an activation of the motor-driven vehicle door member.

11. A non-transitory digital data memory on which is stored a software module for carrying out the method as claimed in claim 1, wherein the method steps to be conducted comprise computer-readable program code of the software module and that is executable by a processor unit.
